(19) United States
(12) Patent Application Publication
(10) Pub. No.: US 2006/0148227 A1
(43) Pub. Date: Jul. 6, 2006

(54) Method for fabricating a first contact hole plane in a memory module

(75) Inventors: Matthias Kronke, Dresden (DE); Joachim Patzer, Dresden (DE); Werner Graf, Dresden (DE)

Correspondence Address: MORRISON & FOERSTER LLP, 1650 TYSONS BOULEVARD, SUITE 300, MCLEAN, VA, 22102, US

(73) Assignee: Infineon Technologies AG, Munchen (DE)

(21) Appl. No.: 11/115,385

(22) Filed: Apr. 27, 2005

(30) Foreign Application Priority Data
Apr. 28, 2004 (DE) 10 2004 020 938.3

(51) Int. Cl. H01L 21/4763

(52) U.S. Cl. 438/586; 438/620; 438/587

(57) ABSTRACT

A silicon dioxide layer is formed and a mask layer is deposited and then patterned to produce openings in the mask layer in the region around the gate contacts onto the gate electrode tracks in the logic region. The surface is uncovered around the gate contacts to the gate electrode tracks in the logic region, reducing the silicon dioxide layer. A sacrificial layer covering the gate electrode tracks is formed and patterned to form sacrificial layer blocks above the contact openings for the bit line contacts between the mutually adjacent gate electrode tracks in the cell array region and above the contact openings for the substrate contacts to the semiconductor surface and the gate contacts onto the gate electrode tracks in the logic region. A filling layer is formed between the sacrificial layer blocks, and the sacrificial layer blocks are removed. The contact opening regions are filled with conductive material.

### CLAIM FOR PRIORITY

This application claims priority to German Application No. 10 2004 020 938.3-33, filed Apr. 28, 2004, which is incorporated herein, in its entirety, by reference.

### TECHNICAL FIELD OF THE INVENTION

The invention relates to a method for fabricating a first contact hole plane of a memory module. More specifically, the invention relates to fabricating a first contact hole plane of a dynamic random access memory (DRAM).

### BACKGROUND OF THE INVENTION

DRAMs are composed of a multiplicity of memory cells which are formed regularly in the form of a matrix on a semiconductor wafer. The memory cells in this case have a storage capacitor and a selection transistor, the selection transistor generally being a field effect transistor. During a write or read operation, the storage capacitor is charged or discharged, via the selection transistor, with an electrical charge corresponding to the respective data unit (bit). For this purpose, the selection transistor is addressed with the aid of word and bit lines. In order to be able to address the individual memory cells and to control the memory access, additional components, in particular switching transistors also formed as field effect transistors, are provided on the DRAM, preferably in the peripheral region.

The individual components on the DRAMs are generally realized with the aid of the silicon planar technique. The planar technique comprises a sequence of individual processes which, in each case, act over the whole area at the semiconductor surface and, by suitable masking layers, lead in a targeted manner to the local alteration of the semiconductor material. In this case, the selection transistors in the cell array region and the switching transistors in the logic region, which are both generally field-effect transistors, are embodied in such a way that two highly doped diffusion regions are formed in the silicon wafer, which form source and drain electrodes. A channel is formed between these two diffusion regions, via which channel an electrically conductive connection can be produced with the aid of a gate electrode formed above the channel. In the case of DRAMs, the gate electrodes of the field effect transistors are realized as gate electrode tracks which form the word lines of the DRAM in the cell array region. The bit lines run transversely over the gate electrode tracks and produce a conductive connection between a bit line and a source/drain electrode of the selection transistor of a memory cell in the inter-space between two gate electrode tracks.

The bit line contacts are usually fabricated as a so-called self-aligned contact in the DRAM fabrication process. For this purpose, on the silicon wafer, on which the gate electrode tracks have been formed in a manner spaced apart equidistantly in the cell array region, firstly an insulation layer is formed and then a sacrificial layer that completely covers the gate electrode tracks is formed. With the aid of a lithography step, the regions at which the bit line contacts are intended to be produced are then defined on the sacrificial layer. These contact regions are then uncovered with the aid of a selective opening of the sacrificial layer. The insulator layer is subsequently removed in the opening regions by a further anisotropic etching. However, the insulator layer remains on the sidewalls of the gate electrode tracks. In a final process step, the contact openings are then filled with a conductive material in order to produce the bit line contacts.

In addition to the formation of the bit line contacts, the gate electrode tracks of the switching transistors and the silicon substrate in the logic region are also connected in the context of the first metallization plane. In this case, however, the formation of the contact holes in the logic region for the purpose of fabricating the substrate and gate electrode track contacts is effected separately from the formation of the contact holes for the bit line contacts in the cell array region by an autonomous lithography process, since there is otherwise the risk of damaging the gate electrode tracks around the bit line contacts during the contact hole etching, which may then lead to a short circuit between the bit line contacts and the gate electrode tracks.

In order that the gate electrode tracks are protected during the contact hole etching, a thick protective layer, generally a nitride cap, is provided on the gate electrode tracks. However, the protective layer then has to be etched through beforehand when the gate electrode tracks are intended to be connected in the logic region. If the contact holes for the bit line contacts are also opened at the same time during this etching, there is the risk of the protective layer of the gate electrode tracks being concomitantly attacked and damaged around the bit line contacts, which may then lead to a short circuit between bit line contact and gate electrode track.

The need to implement separate lithography processes with autonomous masks for forming the bit line contacts in the cell array region and the substrate and gate contacts in the logic region leads to high additional costs since separate masks have to be produced.

Moreover, the double mask process necessitates an additional complicated alignment of the two mask planes in order to avoid imaging errors. The use of silicon nitride covering layers on the gate electrode tracks furthermore leads, owing to the high dielectric constant of silicon nitride, to a strong coupling between the conductive material in the bit line contacts and the gate electrode tracks, so that there is the risk of the electrical properties of the memory cells being impaired.

US 2003/8453 A1 discloses a method for fabricating a first contact hole plane in which a sacrificial layer is formed in the cell array region and in the logic region of a DRAM with gate tracks, the sacrificial layer being patterned in such a way that a sacrificial layer block remains at those locations at which a contact window is intended to be produced later. A filling layer covers the sacrificial layer blocks, which are removed after the uncovering thereof in order to form the desired contact windows, which are then filled with conductive material. U.S. Pat. No. 6,010,935 discloses a method for fabricating the first contact hole plane in which a gate covering layer and an insulator layer comprise silicon dioxide and an oxide layer formed thereon for the contact hole plane made of polysilicon. U.S. Pat. No. 6,503,789 B1 discloses a further method for fabricating a contact hole plane, in which the removal of an insulation layer made of silicon dioxide in the logic region is effected by a first mask and the complete removal of cover layers and gate tracks in the logic region is effected by a second mask. Furthermore, in the cell array, a contact is formed after the removal of the covering layer at the gate tracks in order then to be able to simultaneously etch the contact holes. U.S. Pat. No. 6,300,178 B1 further describes a method in which contacts are produced in the cell array region and the covering layers are removed or thinned at the gate tracks in the logic region, but no sacrificial contact is provided.

### SUMMARY OF THE INVENTION

It is an object of the invention to provide an optimized process implementation for fabricating a first contact hole plane of a memory module, which is distinguished by a simple, reliable and confirmation-free fabrication of bit line contacts in the cell array region and substrate and gate contacts in the logic region.

According to a preferred embodiment of the invention, in order to fabricate a first contact hole plane of a memory module on a semiconductor substrate with a cell array region and a logic region, which in each case have an arrangement of mutually adjacent gate electrode tracks on the semiconductor surface, the gate electrode tracks are preferably provided with a silicon dioxide covering layer and an insulator layer provided between the gate electrode tracks. A silicon dioxide layer is preferably formed on the insulator layer and then a first mask layer is preferably deposited. The first mask layer is preferably patterned in order to produce openings in the first mask layer around the envisaged gate contacts onto the gate electrode tracks in the logic region. Afterward, on the basis of the patterned mask layer, the surface in the region around the gate contacts is preferably uncovered, the thickness of the silicon dioxide layer on the gate electrode track thereby being reduced. After the removal of the first mask layer, a sacrificial layer that covers the gate electrode tracks may be formed and then a second mask layer may be deposited, which may be patterned in turn in order to define the contact openings for the bit line contacts between the mutually adjacent gate electrode tracks in the cell array region and the contact openings for the substrate contacts onto the semiconductor surface and for the gate contacts onto the gate electrode tracks in the logic region. Afterward, the sacrificial layer may be etched anisotropically in order to form sacrificial layer blocks above the contact openings for the bit line contacts between the mutually adjacent gate electrode tracks in the cell array region and above the contact openings for the substrate contacts onto the semiconductor surface and the gate contacts onto the gate electrode tracks in the logic region. After the removal of the second mask layer, the horizontal areas of the semiconductor surface may then be uncovered, the thicknesses of the silicon dioxide covering layers are thereby reduced and spacers comprising insulator layer and silicon dioxide layer remain laterally on the gate electrode tracks. Afterward, a filling layer may be formed between the sacrificial layer blocks in order then to remove the sacrificial layer blocks from the filling layer. A next step preferably involves etching free the horizontal surfaces of the gate electrode tracks and of the semiconductor surface in the region of the uncovered contact openings, lateral covers comprising insulator layer and oxide layer remaining in the contact openings for the bit line contacts at the gate electrode tracks. In order to complete the bit line contacts, the contact opening regions are preferably subsequently filled with conductive material.

According to a preferred embodiment of the invention, the openings for the bit line contacts in the cell array region and for the substrate and gate contacts in the logic region can be produced simultaneously by a single lithography process using only one exposure mask, which leads to cost savings. At the same time, the integration of bit line contact fabrication in the cell array region and substrate and gate contact fabrication in the logic region to form a single lithography process with only one exposure mask enables a high positional accuracy of the contacts and thus contributes to a miniaturization of the chip size, since the safety clearance with respect to the contacts can turn out to be smaller owing to the more precise alignment processes. In comparison with the conventional methods in which the alignment process between the active layer of the components of the first contact hole plane and the metallization plane adjoining the latter had to be effected indirectly by four steps since the contacts were fabricated in separate lithography processes, the invention affords the possibility of implementing the alignment process of the first contact hole plane directly with regard to the underlying active layer and the alignment process of the first metallization plane once again directly with regard to the contact hole plane. Furthermore, as a result of the integrated design according to the invention, in particular of the gate and substrate contacts in the logic region, there is the possibility of forming the substrate contacts in an overlapping manner with the gate electrode tracks, as a result of which chip area can additionally be saved. By using a silicon dioxide covering layer instead of a conventional nitride covering layer on the gate electrode tracks with the use of a silicon dioxide liner instead of the silicon spacers conventionally used, it is possible to achieve a reduced coupling between the surrounding conductive layers, in particular between bit line and word line and bit line and substrate, since silicon dioxide is distinguished by a significantly lower dielectric constant compared with nitride. Moreover, the oxide etchings for forming the contacts are significantly milder, in particular for the gate electrode track structure, than the conventional nitride etching.

In accordance with one preferred embodiment, there is the possibility, in a further additional, preferably isotropic, etching process, of reducing the cross section of the sacrificial layer blocks and thus of forming particularly small contact openings with a reduced area requirement. One advantage in this case is that the smaller contacts produced reduce the coupling capacitance further. At the same time, the risk of a short circuit in the case of imperfect alignment of the next metallization plane is also reduced, which can in turn be utilized to miniaturize the chip. Moreover, sub-lithographic structures can thus be formed in a simple manner. Furthermore, defining the contact opening by way of sacrificial layer blocks ensures a simple filling process in the inverse formation of the conduct openings by way of a glass layer.

In accordance with one preferred embodiment, the sacrificial layer for forming the sacrificial layer blocks which define the contact openings is a polysilicon layer, which is patterned with a hard mask layer. With this procedure of an inverse formation of the contact openings above sacrificial layer blocks, even extremely small contact structures can be formed reliably and exactly.

In accordance with a further preferred embodiment, a glass layer is used as a filling layer for filling the interspaces between the sacrificial layer blocks, the glass layer being planarized by a chemical mechanical polishing step, in which the surface of the sacrificial layer blocks is uncovered. The planarization step can be implemented simply and precisely in this case since the sacrificial layer blocks, in particular also in the logic region, enable an endpoint determination. When etching back the silicon dioxide layer on the gate electrode tracks in the logic region, the procedure is preferably such that the remaining layer thickness essentially corresponds to the layer thickness of insulator layer and silicon dioxide layer on the semiconductor surface between the gate electrode tracks in the cell array region. This design ensures that when the surfaces are intended to be uncovered after the removal of the sacrificial layer blocks in the contact openings, a uniform etching for opening the bit line contacts between the gate electrode tracks in the cell array region and the gate contacts on the gate electrode tracks in the logic region is ensured. In this case, it is preferred to use, as end point determination for anisotropically etching free the horizontal surfaces, a material removal of the semiconductor substrate in the cell array region and/or or a material removal from the gate electrode tracks in the logic region.

### BRIEF DESCRIPTION OF THE DRAWINGS

The invention is explained in more detail below on the basis of the exemplary embodiments specified in the schematic figures of the drawings, in which:

FIG. 1 shows a cross section through a silicon wafer in a first process stage of the process sequence according to an embodiment of the invention;

FIG. 2 shows a cross section through a silicon wafer in a further process stage of the process sequence according to an embodiment of the invention;

FIG. 3 shows a cross section through a silicon wafer in still a further process stage of the process sequence according to an embodiment of the invention;

FIG. 4 shows a cross section through a silicon wafer in still a further process stage of the process sequence according to an embodiment of the invention;

FIG. 5 shows a cross section through a silicon wafer in still a further process stage of the process sequence according to an embodiment of the invention;

FIG. 6 shows a cross section through a silicon wafer in still a further process stage of the process sequence according to an embodiment of the invention;

FIG. 7 shows a cross section through a silicon wafer in still a further process stage of the process sequence according to an embodiment of the invention;

FIG. 8 shows a cross section through a silicon wafer in still a further process stage of the process sequence according to an embodiment of the invention;

FIG. 9 shows a cross section through a silicon wafer in still a further process stage of the process sequence according to an embodiment of the invention; and

FIG. 10 shows a cross section through a silicon wafer in still a further process stage of the process sequence according to an embodiment of the invention.

### DETAILED DESCRIPTION OF THE INVENTION

The invention is explained by way of example on the basis of a process sequence for fabricating a first contact hole plane in a DRAM module with a cell array region and a logic region on a silicon wafer. However, it can also be used for other memory modules, e.g. embedded DRAM or SRAM modules, in which contacts are to be embodied simultaneously in a cell array region and a logic region.

The figures in each case illustrate a cross section through a detail from a pre-patterned silicon wafer on which a cell array region and a peripheral logic region are provided. In this case, the memory cells of the DRAM are composed of a selection transistor (not shown) and a storage capacitor (not shown). The peripheral logic region contains various elements, in particular switching transistors (not shown) for addressing the memory cells. Trench isolations, so-called STI regions (shallow trench isolation), are formed for the purpose of insulating the different components in the cell array region and in the logic region.

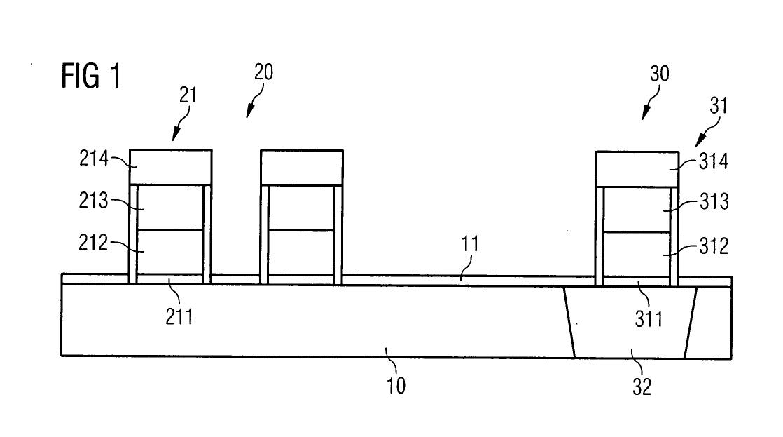

FIG. 1 shows the starting point for the method according to the invention, a pre-patterned silicon wafer 10 on which a cell array 20, represented by two gate electrode tracks 21 running parallel, and a logic region 30 separate therefrom, represented by a further gate electrode track 31, are formed. The gate electrode track in the logic region runs in the region of the gate contact provided on a trench isolation layer 32 formed in the silicon substrate 10.

The gate electrode tracks 21, which form the wordlines in the cell array region 20, and the gate electrode track 31 in the logic region are respectively placed on a silicon dioxide layer 211, 311, which, in the transistor region, isolates the gate electrode track from the channel region, and comprise an electrode layer 212, 312, preferably a polysilicon layer, and a contact layer 213, 313, preferably a tungsten and/or tungsten nitride layer. The gate electrode stack is terminated by a covering layer 214, 314, which is intended to protect the conductive layer stack against damage during subsequent process steps. The covering layer 214, 314 is produced from silicon dioxide according to the invention, this being distinguished by a low dielectric constant, thereby marginally avoiding dielectric couplings between the gate electrode stack and adjacent conductive layers.

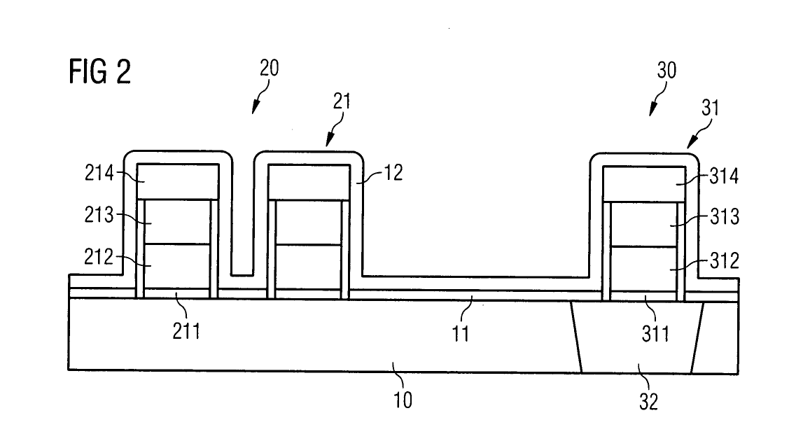

The silicon wafer 10 and the gate electrode tracks 21, 31 arranged thereon are furthermore enclosed by a thin layer serving as a diffusion barrier, preferably a silicon dioxide layer 11. In a first process step, a silicon dioxide layer 12 is then applied to this silicon wafer 10 pre-patterned in this way with the gate electrode tracks 21, 31. In this case, the silicon dioxide layer 12 is preferably deposited with the aid of a so-called LPCVD method, which ensures a high conformity of the silicon dioxide layer 12. The silicon dioxide layer 12 serves as an insulating spacer between the gate electrode tracks 21, 31. A cross section through the silicon wafer after this process step is shown in FIG. 2.

Afterward, in a further process step, a mask layer 13, preferably a photo resist layer, is spun onto the silicon wafer 10 in large-area fashion, which layer completely covers the gate electrode tracks 21, 31 and has an essentially plane surface. On the mask layer 13, a region around envisaged gate contacts onto the gate electrode tracks 31 in the logic region is defined by a lithography method using one exposure mask (not shown). For this purpose, a light-sensitive photo resist is applied to the mask layer 13 and exposed with the aid of the exposure mask which has the structure with the region around the gate contacts in the logic region as a design plane. The photo resist is subsequently developed in order to remove the exposed locations. The first mask layer 13 is then etched anisotropically with the aid of the photo resist layer as a masking layer. As an alternative, there is also the possibility, when the mask layer 13 is a photo resist layer, of exposing the latter directly with the aid of the exposure mask and opening the region around the gate contacts in the logic region 30 by development.

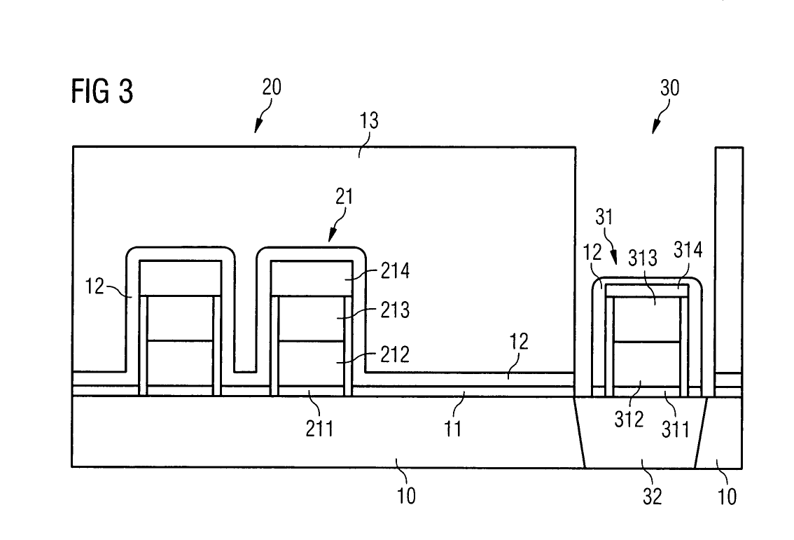

After the patterning of the mask layer 13, a further etching is effected to etch through the silicon dioxide layer stack comprising silicon dioxide layer 11 and spacer layer 12 around the gate contacts to the gate electrode track 31 in the logic region 30. This involves thinning the silicon dioxide layer on the gate electrode track 31, which is composed of the covering layer 314 and the spacer layer 12, preferably to a layer thickness which essentially corresponds to the layer thickness of silicon dioxide layer 11 and spacer layer 12 on the silicon wafer surface 10. This procedure ensures that the thick silicon dioxide layer on the gate electrode tracks 31 in the region of the gate contacts is thinned only in accordance with the layer thickness of silicon dioxide layer 11 and spacer layer 12, thus leaving a sufficient protection of the conductive layer stack of the gate electrode track 31 during subsequent etchings. A cross section through the silicon wafer after this process step is illustrated in FIG. 3.

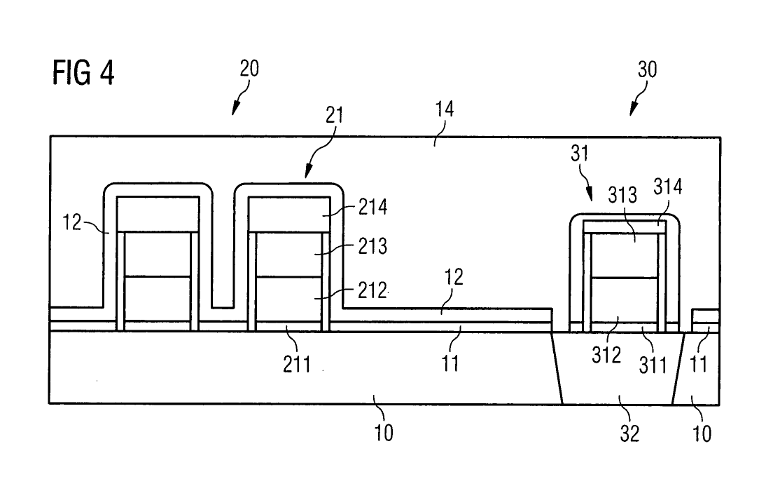

Afterward, as shown in FIG. 4, a sacrificial layer 14, preferably a polysilicon layer, is then deposited on the silicon wafer 10 in large-area fashion with the aid of an LPCVD method. In order to obtain a planar surface of the sacrificial layer 14, the surface is planarized after deposition preferably with the aid of the chemical mechanical polishing process. The sacrificial layer 14 may also optionally be produced in such a way that a first sacrificial layer is applied and the latter is polished down to the silicon dioxide covering layer 214 of the gate electrode tracks 21 with the aid of a so-called stop polishing process. A particularly planar surface can be obtained as a result of this. In a further deposition process, a further sacrificial layer is then produced with the desired target thickness above the gate electrode tracks, preferably a layer thickness of 50 to 1000 nm. This results in a plane covering of the gate electrode track structure 21, 31 in the cell array region 20 and in the logic region 30 on the silicon wafer 10. A cross section through the silicon wafer 10 after this process step is illustrated in FIG. 4.

In a further process sequence, the regions of the bit line contacts in the cell array region 20 and of the substrate and gate contacts in the logic region 30 are defined on the plane sacrificial layer surface 14. This involves depositing a hard mask layer, generally a silicon nitride layer, on the sacrificial layer 14, which is patterned with the aid of the lithography technique. For this purpose, an antireflection layer and then a resist layer are applied to the hard mask layer. The antireflection layer provides for an improved exposure of the resist layer since the antireflection layer essentially prevents reflections of light at the interface. Furthermore, the antireflection layer ensures an improved adhesion of the resist material. The resist layer is then exposed with the aid of an exposure mask that covers the regions in which the contact openings for the bit line contacts in the cell array region and the substrate and gate contacts in the logic region are provided. The resist layer is subsequently developed, the exposed resist structures being stripped away outside the contact opening regions. With the aid of an anisotropic etching, the structure of the resist mask is then transferred into the hard mask layer and the residual resist layer is subsequently removed to leave hard mask plugs on the sacrificial layer 14.

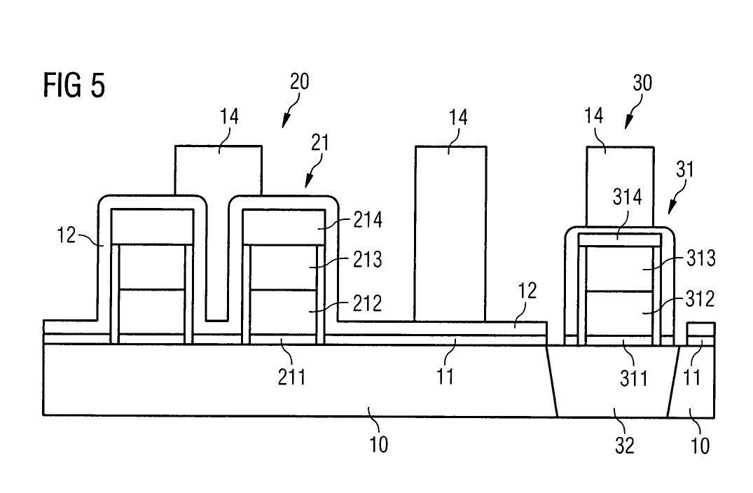

Using the hard mask plugs as a masking layer, the sacrificial layer material is then completely removed outside the regions concealed by the hard mask plugs by an anisotropic etching in a next process step. This anisotropic sacrificial layer etching for producing blocks in the region of the envisaged contact openings is highly selective with respect to the underlying spacer layer 12 comprising silicon dioxide so that the spacer layer is essentially not attacked. Afterward, the remaining hard mask layer is removed from the sacrificial layer blocks 14 with the aid of an etching, preferably a wet-chemical etching. A cross section through the silicon wafer after the formation of the sacrificial layer blocks 14 is illustrated in FIG. 5. The sacrificial layer blocks 14, which define the contact opening, may be patterned further in the context of a further, preferably isotropic, sacrificial layer etching, in particular may be reduced with regard to their cross section, in order to fabricate particularly small contact openings and thus to save chip area.

In a further process step, the horizontal surfaces of the silicon wafer 10 are then uncovered with the aid of an anisotropic silicon dioxide etching. The horizontal silicon dioxide layers on the gate electrode tracks 21 are simultaneously thinned in this case. The vertical spacer layers on the sidewalls of the gate electrode tracks are not attacked, however. The anisotropic silicon dioxide etching is preferably stopped by an end point signal. In this case, the released material removal of the silicon wafer 10 is preferably used as the end point signal.

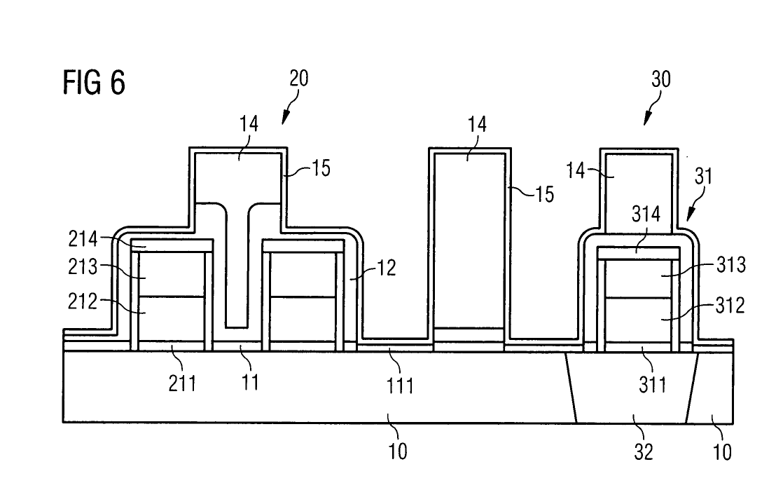

A thin silicon dioxide layer 111 is then applied as a screen oxide. Through the screen oxide layer 111 of the silicon wafer 10, it is then possible to perform desired dopings in the silicon surface with the aid of standard processes for forming DRAM components. After the formation of the doped regions in the silicon surface, in a next process step, a liner layer 15 is deposited conformally as a diffusion barrier, preferably a silicon nitride or silicon oxynitride layer. A cross section through the silicon wafer after this process step is shown in FIG. 6.

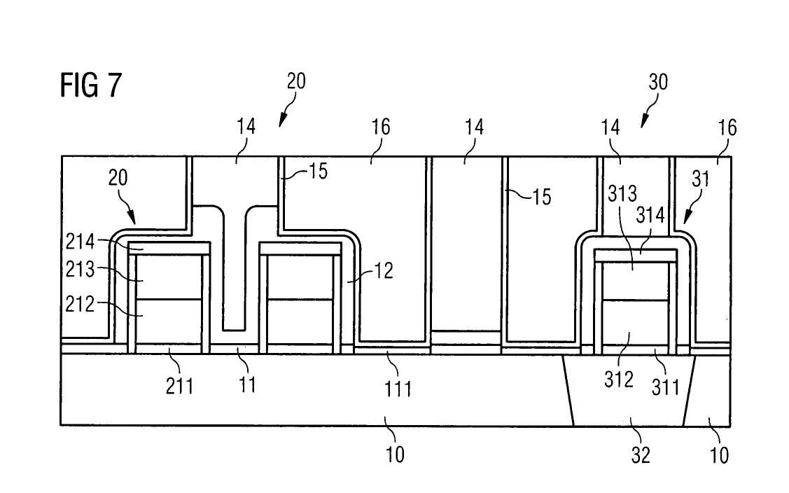

A vitreous layer, preferably a BPSG layer 16, is then deposited onto the liner layer 15 and is exposed to a heating step to make it flow, which effects densification and filling of gaps. The BPSG layer 16 is subsequently planarized with the aid of a chemical mechanical polishing process. In this case, the chemical mechanical polishing process is preferably designed in such a way that it is stopped by an end point determination. In this case, an ammonia signal may be utilized as the end point determination, the ammonia signal arising if the silicon nitride or silicon oxynitride liner layer 15 on the sacrificial layer blocks 14 is polished away during the chemical mechanical polishing process. By virtue of the fact that sacrificial layer blocks 14 which define the contact openings for the bit line contacts in the cell array region 20 and the substrate and gate contacts in the logic region 30 are distributed over the entire silicon wafer 10, a highly plane BPSG surface can be achieved, the surface of the sacrificial layer blocks which define the contact openings being uncovered. A cross section through the silicon wafer after the planarization process is illustrated in FIG. 7.

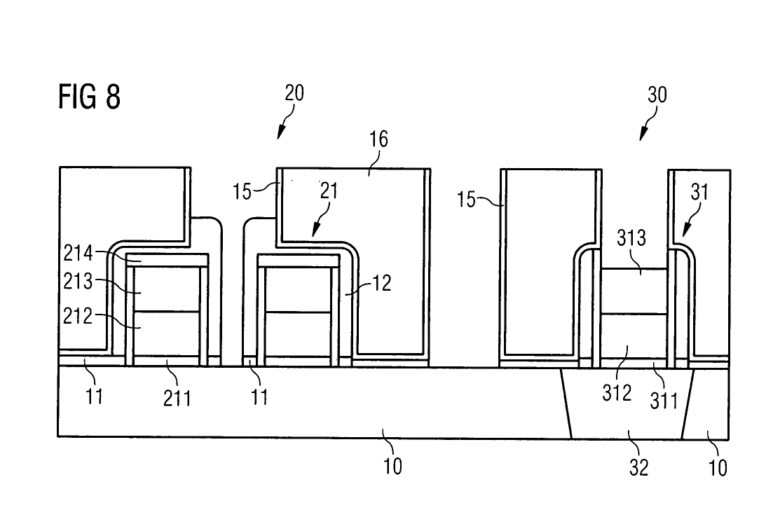

A further process sequence involves simultaneously opening the surface of the silicon wafer 10 in the region of the contact openings in the cell array region 20 and in the logic region 30. For this purpose, in a first step, the sacrificial layer blocks 14 are completely removed from the BPSG layer 16 preferably by an isotropic etching. In this case, the sacrificial layer etching need not contain a sputtering component, but rather only has to be selective with respect to the silicon dioxide spacers 12, the liner layer 15 and the BPSG layer 16. If polysilicon is used as the sacrificial layer material, a dry etching is preferably carried out. After the removal of the sacrificial layer blocks 14 from the BPSG layer 16, the surface of the silicon wafer 10 is uncovered by an anisotropic silicon dioxide etching. This simultaneously removes the silicon dioxide layer 11 on the surface of the gate electrode tracks 21 in the logic region 30. A cross section through the silicon wafer 10 with opened contact holes in the cell array region 20 between the gate electrode tracks for forming the bit line contacts and in the logic region for forming the substrate and gate electrode track contacts is illustrated in FIG. 8.

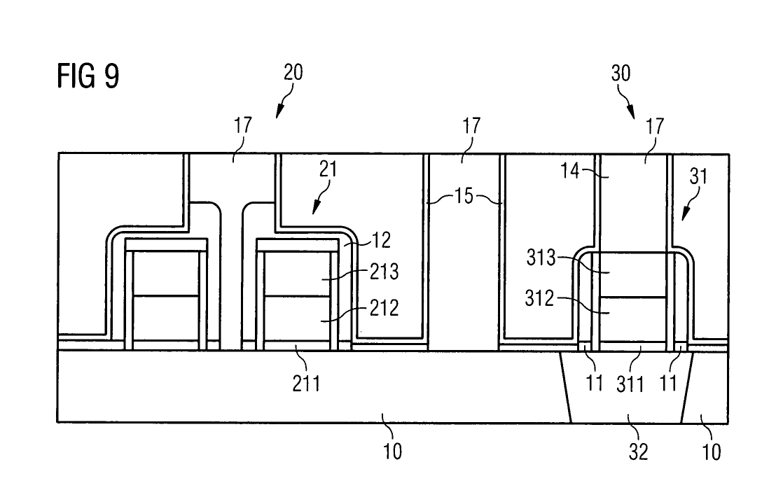

In order to implement the contact holes, all of the contact openings are then filled with conductive material, preferably tungsten. All known material deposition methods may be used in this case. In the case of a tungsten filling, there is the possibility of firstly applying a tungsten liner, e.g. made of titanium/titanium nitride, and then performing a large-area filling of the contact openings, the metal layer 17 then being removed as far as the surface of the BPSG layer 16, thus producing a cross section of the silicon wafer such as is illustrated in FIG. 9, in which the contact openings are filled with conductive material blocks 17.

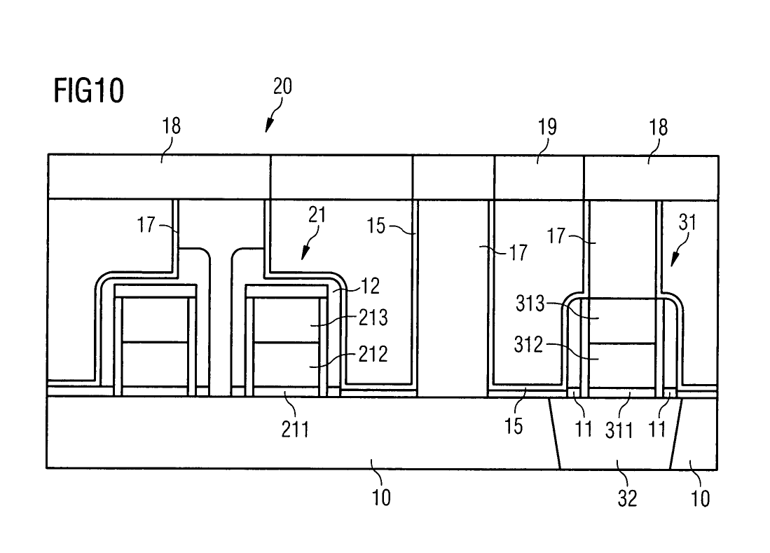

Finally, a further large-area deposition of a conductive material, in particular tungsten or aluminum, is then performed in a further process sequence for forming the first metallization plane M0. This metal plane is then patterned with the aid of the photolithography technique in order to perform the wiring of the bit line contacts in the cell array region 10 and of the substrate and gate contacts in the logic region 30. A silicon dioxide layer 19 is preferably provided between the individual interconnects 18 for insulation purposes. A cross section through the silicon wafer after the formation of the first wiring plane is illustrated in FIG. 10. Further metallization planes for the wiring of the individual components are then produced in the context of the design of the DRAM process.

The process sequence according to the invention makes it possible for the first contact hole plane to be patterned and opened essentially by a single lithography process. In this case, a silicon dioxide layer can advantageously be formed as a covering layer on the gate electrode tracks, and is thinned in a mask process prior to the actual contact hole lithography. The silicon dioxide covering layer is furthermore distinguished by a reduction of the electrical coupling to the adjacent conductive layers. The simultaneous patterning of all the contact holes in the first contact hole plane both in the cell array region and in the logic region with sacrificial layer blocks makes it possible, in particular, to perform a simplified and reliable opening and filling of the contact holes. The simultaneous patterning of all the contact holes furthermore provides for a simplified alignment process and furthermore enables chip area to be saved on account of an increased positional accuracy.

What is claimed is:

1. A method for fabricating a first contact hole plane of a memory module, comprising:
providing a semiconductor substrate with a cell array region and a logic region, which each have an arrangement of mutually adjacent gate electrode tracks on a semiconductor surface, the gate electrode tracks being provided with a silicon dioxide covering layer and an insulator layer being provided between the gate electrode tracks;
forming a silicon dioxide layer on the insulator layer;
depositing a first mask layer;
patterning the first mask layer to open the first mask layer around gate contacts on the gate electrode tracks in the logic region;
anisotropically etching free a surface in the region around the uncovered gate contacts to the gate electrode tracks in the logic region, the thickness of the silicon dioxide covering layer thereby being reduced;
removing the first mask layer;
forming a sacrificial layer, the gate electrode tracks thereby being covered;
depositing a second mask layer;
patterning the second mask layer to define contact openings for bit line contacts between the mutually adjacent gate electrode tracks in the cell array region and contact openings for substrate contacts to the semiconductor surface and for the gate contacts onto the gate electrode tracks in the logic region;
anisotropically etching the sacrificial layer to form sacrificial layer blocks above the contact openings for the bit line contacts between the mutually adjacent gate electrode tracks in the cell array region and above the contact openings for the substrate contacts to the semiconductor surface and the gate contacts onto the gate electrode tracks in the logic region;
removing the second mask layer;
anisotropically etching free the semiconductor surface;
forming a filling layer between the sacrificial layer blocks;
removing the sacrificial layer blocks in the filling layer;
anisotropically etching free the gate electrode tracks and the semiconductor surface in the region of the uncovered contact openings, whereby lateral covers, comprising the insulator layer and the silicon dioxide layer, remain in the contact openings for the bit line contacts at the gate electrode tracks; and
filling the contact opening regions with a conductive material.

2. The method as claimed in claim 1, after the anisotropic etching of the sacrificial layer to form the sacrificial layer blocks, the cross section of the sacrificial layer blocks is reduced by a further isotropic etching.

3. The method as claimed in claim 1, wherein the insulator layer between the gate electrode tracks is a silicon dioxide layer.

4. The method as claimed in claim 1, wherein the sacrificial layer for covering the gate electrode tracks is a planarized polysilicon layer and the second mask layer is a hard mask layer.

5. The method as claimed in claim 1, wherein a liner layer is provided below the filling layer when the filing layer is formed.

6. The method as claimed in claim 5, wherein the liner layer comprises at least one of a silicon oxide layer, a silicon nitride layer and a silicon oxynitride layer.

7. The method as claimed in claim 1, wherein the formed filling layer is a doped glass layer which is produced using reflow technology and is planarized by a chemical mechanical polishing step in which the surface of the sacrificial layer blocks is uncovered.

8. The method as claimed in claim 1, wherein a layer thickness of the silicon dioxide covering layer on the gate electrode tracks in the logic region which remain after anisotropically etching through the surface in the region around the uncovered gate contacts onto the gate electrode tracks in the logic region corresponds to a layer thickness of insulator layer and oxide layer on the semiconductor surface between the gate electrode tracks.

9. The method as claimed in claim 1, wherein at least one of a material removal of the semiconductor substrate in the cell array region and a material removal of the gate electrode tracks in the logic region is used for end point determination while anisotropically etching free the gate electrode tracks and the semiconductor surface in the region of the uncovered contact openings.
